(19) United States
(12) Patent Application Publication
(10) Pub. No.: US 2026/0059770 A1
(43) Pub. Date: Feb. 26, 2026

(54) CHARGE TRAP-CONTROLLED SELECTOR-MEMORY DEVICE

(71) Applicant: ELECTRONICS AND TELECOMMUNICATIONS RESEARCH INSTITUTE, Daejeon (KR)

(72) Inventor: Jung-Wook LIM, Daejeon (KR)

(21) Appl. No.: 19/296,194

(22) Filed: Aug. 11, 2025

(30) Foreign Application Priority Data
Aug. 20, 2024 (KR) 10-2024-0111331
Jul. 7, 2025 (KR) 10-2025-0090563

(51) Int. Cl. H10B 63/00

(52) U.S. Cl. CPC H10B 63/24; H10B 63/30

(57) ABSTRACT

Disclosed herein is a charge trap-controlled selector-memory device. The charge trap-controlled selector-memory device may include selector memory, an upper electrode stacked on a top of the selector memory and configured such that a voltage is applied to the upper electrode, a lower electrode stacked on a bottom of the selector memory and grounded, and an ultra-thin film charge trap layer stacked on an interface between the selector memory and the upper electrode or the lower electrode, and configured to trap electrons or holes as the voltage is applied to the upper electrode.

### CROSS REFERENCE TO RELATED APPLICATIONS

This application claims the benefit of Korean Patent Application Nos. 10-2024-0111331, filed Aug. 20, 2024 and 10-2025-0090563, filed Jul. 7, 2025, which are hereby incorporated by reference in their entireties into this application.

### BACKGROUND OF THE INVENTION

### 1. Technical Field

The following embodiments relate to artificial intelligence semiconductor technology.

### 2. Description of Related Art

Due to the expansion of artificial intelligence semiconductors and limitations faced in semiconductor high integration, a transition to a new technology is now required. A conventional computer is implemented with a computing device and memory that are separately configured. In this case, when processing massive amounts of data, the conventional computer causes time delays or high power consumption, thus requiring more effective computation.

For this, a Compute Express Link (CXL) technology for smooth connections has been developed, and new memory that is usable for a nonvolatile purpose while operating at a high speed is under development. For this, Intel developed X-point memory using phase-change memory. However, due to high leakage current, a device in which a selector material for reducing the leakage current was connected in series to a memory material was developed and commercialized. However, when high integration is performed, such a device was proved ineffective in terms of efficiency due to issues such as high aspect ratio and void formation and was eventually phased out.

Referring to Prior Art Document 1 (Publication No. 10-2024-0098550, SK Hynix, Korea, published on June 28, 2024) and Prior Art Document 2 (Publication No. 10-2022-0021550, Samsung Electronics, Korea, published on February 22, 2022), a selector was fundamentally developed by being incorporated into a semiconductor device in a structure connected in series to memory.

Subsequently, SK Hynix developed a selector which performs a memory function and announced a Selector-Only Memory (SOM) device. This SOM device adopts a scheme in which the threshold voltage of the selector is modulated by pulses with different polarities to exhibit the memory function. This is a highly encouraging result in overcoming the aspect ratio issue, and the SOM device is rapidly emerging as next-generation memory for CXL.

However, since such a SOM device uses complex quaternary or higher-order compound materials, simpler compound materials are needed to establish semiconductor processes such as etching and to ensure high yield.

Also, the current SOM structure performs a memory function using a scheme for supplying pulses with different polarities to modulate threshold voltages. However, a clear mechanism for this SOM structure has not yet been reported, and it is not certain whether uniform operating characteristics can be achieved over a larger area.

Therefore, there is a need to discover materials that can perform two functions of a selector and memory using binary or, at most, ternary compound materials while operating as a clearer conduction mechanism and to develop device structures for the materials.

### SUMMARY OF THE INVENTION

An embodiment is intended to propose a selector-memory device that meets a recent increase in a demand for an artificial intelligence semiconductor and that is capable of replacing conventional Dynamic Random Access Memory (DRAM) as next-generation low-power and high-speed memory, which conforms to such a demand increase.

An embodiment is intended to propose a device that can perform two functions of a selector and memory using binary or, at most, ternary compound materials while operating as a clearer conduction mechanism.

In accordance with an aspect, there is provided a charge trap-controlled selector-memory device, including selector memory, an upper electrode stacked on a top of the selector memory and configured such that a voltage is applied to the upper electrode, a lower electrode stacked on a bottom of the selector memory and grounded, and an ultra-thin film charge trap layer stacked on an interface between the selector memory and the upper electrode or the lower electrode, and configured to trap electrons or holes as the voltage is applied to the upper electrode.

The selector memory may be formed of a chalcogenide-based compound, and includes at least one of binary or ternary materials, or a combination thereof, and the selector memory may be made of a material including SiTe, SiSeTe, ZnTe, and ZnSeTe.

The selector memory may be manufactured to be deposited on the lower electrode using a semiconductor vacuum technique including Atomic Layer Deposition (ALD), sputter deposition, or chemical vapor deposition.

The selector memory may have a thickness of 5 nm to 200 nm.

The ultra-thin film charge trap layer may have a thickness of 0.5 nm to 10 nm.

The ultra-thin film charge trap layer may be formed of one of an oxide and a sulfide.

The charge trap-controlled selector-memory device may further include a charge supply layer stacked between the ultra-thin film charge trap layer and the lower electrode or the upper electrode to supply electrons or holes.

The charge supply layer may be formed of one of an oxide and a sulfide.

The charge supply layer may have a thickness of 5 nm to 50 nm.

In accordance with another aspect, there is provided a charge trap-controlled selector-memory device, including a gate electrode, a gate dielectric layer formed to contact a first side surface of the gate electrode, a charge trap layer formed on a top of the gate dielectric layer to trap electrons or holes, a selector formed on a top of the charge trap layer, a drain electrode connected to a first side of the selector on the top of the gate dielectric layer, and a source electrode connected to a second side of the selector on the top of the gate dielectric layer.

The gate dielectric layer may be a normal dielectric layer or a charge supply dielectric layer.

The selector may have a thickness of 5 nm to 50 nm.

The charge trap layer may trap electrons or holes supplied from the selector or a charge supply dielectric layer as a voltage pulse or a DC voltage is applied to the gate electrode, and a threshold voltage of the selector may be modulated.

In accordance with a further embodiment, there is provided a charge trap-controlled selector-memory device, including a cylindrical first electrode configured such that a voltage is applied thereto, cylindrical selector memory inserted into the first electrode, a cylindrical second electrode inserted into the selector memory and grounded, and an ultra-thin film charge trap layer inserted into an interface between the selector memory and the second electrode or the first electrode, and configured to trap electrons or holes as a voltage is applied to the first electrode.

The selector memory may be formed of a chalcogenide-based compound and includes at least one of binary or ternary materials, or a combination thereof.

The charge trap-controlled selector-memory device may further include a charge supply layer stacked between the charge trap layer and the second electrode or the first electrode to supply electrons or holes.

### BRIEF DESCRIPTION OF THE DRAWINGS

The above and other objects, features and advantages of the present disclosure will be more clearly understood from the following detailed description taken in conjunction with the accompanying drawings, in which:

FIG. 1 is a sectional perspective view of a charge trap-controlled selector-memory device having a two-terminal structure according to an embodiment;

FIGS. 2 and 3 are diagrams for explaining the control of the threshold voltage of a selector caused by charge trap in a charge trap-controlled selector-memory device according to an embodiment;

FIG. 4 is a sectional perspective view of a charge trap-controlled selector-memory device having a two-terminal structure according to another embodiment;

FIG. 5 is a diagram illustrating an example of a current-voltage characteristic curve representing a change in the threshold voltage of a selector and an operating process of the selector when electrons are trapped by a charge trap layer in the charge trap-controlled selector-memory device having a two-terminal structure according to another embodiment;

FIG. 6 is a sectional perspective view of a charge trap-controlled selector-memory device having a three-terminal structure according to an embodiment;

FIG. 7 is a diagram illustrating an example of memory modulation characteristics using a gate pulse of a three-terminal transistor device in a charge trap-controlled selector-memory device having a three-terminal structure according to an embodiment;

FIG. 8 is a diagram illustrating an example of memory modulation characteristics using a read voltage of a three-terminal transistor device in a charge trap-controlled selector-memory device having a three-terminal structure according to an embodiment; and

FIG. 9 is a sectional perspective view of a cylindrical charge trap-controlled selector-memory device having a two-terminal structure according to a further embodiment.

### DESCRIPTION OF THE PREFERRED EMBODIMENTS

Advantages and features of the present disclosure and methods for achieving the same will be clarified with reference to embodiments described later in detail together with the accompanying drawings. However, the present disclosure is capable of being implemented in various forms, and is not limited to the embodiments described later, and these embodiments are provided so that this disclosure will be thorough and complete and will fully convey the scope of the present disclosure to those skilled in the art. The present disclosure should be defined by the scope of the accompanying claims. The same reference numerals are used to designate the same components throughout the specification.

It will be understood that, although the terms “first” and “second” may be used herein to describe various components, these components are not limited by these terms. These terms are only used to distinguish one component from another component. Therefore, it will be apparent that a first component, which will be described below, may alternatively be a second component without departing from the technical spirit of the present disclosure.

The terms used in the present specification are merely used to describe embodiments, and are not intended to limit the present disclosure. In the present specification, a singular expression includes the plural sense unless a description to the contrary is specifically made in context. It should be understood that the term “comprises” or “comprising” used in the specification implies that a described component or step is not intended to exclude the possibility that one or more other components or steps will be present or added.

Unless differently defined, all terms used in the present specification can be construed as having the same meanings as terms generally understood by those skilled in the art to which the present disclosure pertains. Further, terms defined in generally used dictionaries are not to be interpreted as having ideal or excessively formal meanings unless they are definitely defined in the present specification.

The present disclosure proposes a charge trap-controlled selector-memory device having a two-terminal or three-terminal structure, as a device that can implement two functions of a selector and memory.

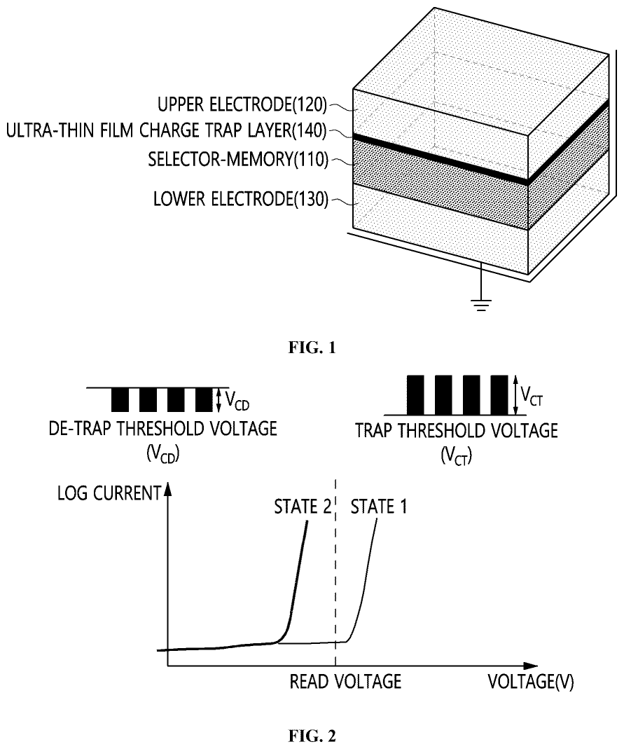

FIG. 1 is a sectional perspective view of a charge trap-controlled selector-memory device having a two-terminal structure according to an embodiment.

Referring to FIG. 1, the charge trap-controlled selector-memory device according to the embodiment may include selector memory 110, an upper electrode 120 which is stacked on the top of the selector memory 110 and to which a voltage is applied, a lower electrode 130 which is stacked on the bottom of the selector memory 110 and is grounded, and an ultra-thin film charge trap layer 140 which is stacked on an interface between the selector memory 110 and the upper electrode 120 or the lower electrode 130 and which traps electrons or holes as the voltage is applied to the upper electrode 120.

Here, the selector memory (SM) 110 may be formed of a chalcogenide-based compound, and may contain at least one of binary or ternary materials or a combination thereof. For example, all of compounds such as SiTe, SiSeTe, ZnTe, and ZnSeTe may be contained in the compound.

Here, the selector memory 110 may be manufactured as a thin film deposited on the lower electrode 130 using any of semiconductor vacuum techniques including Atomic Layer Deposition (ALD), sputter deposition, and chemical vapor deposition.

Here, the selector memory 110 may have a thickness of 5 nm to 200 nm.

Here, the thin-film charge trap layer 140 may be formed of a very thin film which traps electrons or holes, and the thickness of the thin film may be 0.5 nm to 10 nm.

Here, the ultra-thin film charge trap layer 140 may be made of one of an oxide or a sulfide. For example, AlO_{X}, SiO_{X}, HfO_{X}, ZrO_{X}, ZnO_{X}, TiO_{X}, InO_{X}, and SnO_{X} may be used.

In the above-described charge trap-controlled selector-memory device, when a positive voltage or a negative voltage is applied to the upper electrode 120 in the state in which the lower electrode 130 is grounded, electrons or holes are trapped in the ultra-thin film charge trap layer 140, and thus the threshold voltage of the selector memory 110 changes.

Here, the charge trap layer 140 may include two types, that is, an electron trap layer which traps electrons, and a hole trap layer which traps holes.

Also, the charge trap layer 140 may occasionally be implemented in a form in which electrons and holes are competitively trapped.

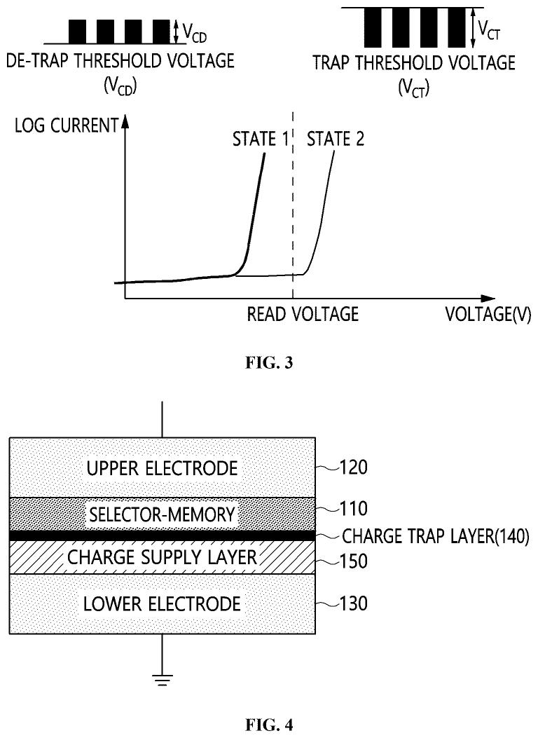

FIG. 2 is a diagram for explaining the control of the threshold voltage of a selector caused by electron trapping in a charge trap-controlled selector-memory device according to an embodiment, and FIG. 3 is a diagram for explaining the control of the threshold voltage of a selector caused by hole trapping in the charge trap-controlled selector-memory device according to an embodiment.

Referring to FIG. 2, a current-voltage characteristic curve representing a change in the threshold voltage of the selector and an operating process of the selector when electrons are trapped by the charge trap layer 140 is illustrated. The ultra-thin film charge trap layer 140 operating as illustrated in FIG. 2 in this way is referred to as an electron trap layer.

When a voltage pulse of V_{CT} (trap threshold voltage) having a higher positive voltage value is applied to the upper electrode 120, electrons are trapped in the electron trap layer 140. Then, since the threshold voltage of the selector moves in a negative direction, the state of the selector changes to state 2, illustrated in FIG. 2.

On the other hand, when V_{CD} (voltage required for detrapping) that is a voltage pulse for detrapping electrons is applied to the upper electrode 120, electrons trapped in the electron trap layer 140 are released.

Here, although the voltage applied to the upper electrode 120 representatively has a negative value, it may also be a positive lower value.

Then, since the threshold voltage of the selector moves in a positive direction, the state of the selector changes to state 1, illustrated in FIG. 3.

On the other hand, referring to FIG. 3, a current-voltage characteristic curve representing a change in the threshold voltage of the selector and an operating process of the selector when holes are trapped by the charge trap layer 140 is illustrated. The ultra-thin film charge trap layer 140 operating as illustrated in FIG. 3 in this way is referred to as a hole trap layer.

When holes are trapped by the hole trap layer, a negative voltage pulse that is a trap threshold voltage is applied, and the threshold voltage moves in a negative direction, as illustrated in FIG. 3, and thus the state of the selector changes to state 1.

On the other hand, when a positive voltage pulse or a negative pulse having a low absolute value is applied for detrapping, holes are detrapped, and the threshold voltage changes to a positive direction, and thus the state of the selector changes to state 2.

Meanwhile, the above-described FIG. 1 illustrates a two-terminal device composed of the selector and the ultra-thin film charge trap layer. This two-terminal device may be extended to add a charge supply layer to the charge trap layer 140, wherein the charge supply layer may be added and bonded to any one of the upper electrode 120 and the lower electrode 130.

FIG. 4 is a sectional perspective view of a charge trap-controlled selector-memory device having a two-terminal structure according to another embodiment.

Referring to FIG. 4, the charge trap-controlled selector-memory device according to the embodiment may further include a charge supply layer 150 which is stacked between the charge trap layer 140 and the lower electrode 130 or the upper electrode 120 to supply electrons or holes.

Here, the charge supply layer 150 may be made of one of an oxide and a sulfide. For example, AlO_{X}, SiO_{X}, HfO_{X}, ZrO_{X}, InO_{X}, CuO_{X}, and MoO_{X} may be included in the charge supply layer 150.

Such a charge supply layer 150 may have a thickness of 5 nm to 50 nm.

The charge supply layer 150 functions to supply electrons or holes and is formed from a non-stoichiometric structure.

Further, when an electric field is applied between the upper electrode 120 and the lower electrode 130, electrons or holes move to the charge trap layer 140 to be trapped, thus changing the threshold voltage of the selector and exhibiting the characteristics of the memory.

FIG. 5 is a diagram illustrating an example of a current-voltage characteristic curve representing a change in the threshold voltage of a selector and an operating process of the selector when electrons are trapped by a charge trap layer in a charge trap-controlled selector-memory device having a two-terminal structure according to another embodiment.

Referring to FIG. 5, in the charge trap-controlled selector-memory device having a two-terminal structure according to another embodiment, when a positive voltage pulse is applied to an upper electrode 120, and a charge supply layer 150 is a layer for supplying electrons, the electrons are moved to and trapped in a charge trap layer 140 with respect to the positive voltage. Generally, the threshold voltage of a selector moves in a positive direction, and thus the state of the selector changes to state 1, as illustrated in FIG. 5.

Also, when a pulse is applied to the upper electrode 120 in a negative direction, the threshold voltage of the selector moves in a negative direction while electrons trapped in the charge trap layer 140 are released, and the state of the selector changes to state 2, as illustrated in FIG. 5.

Depending on this voltage pulse, different threshold voltages corresponding to state 1 and state 2 are obtained, and the selector in which the difference between the threshold voltages becomes a memory area (i.e., memory window) to perform a memory operation is obtained.

Meanwhile, the selector-memory device may be manufactured as not only a two-terminal device but also a three-terminal device. When the three-terminal device is formed, the operational stability of the device is improved, and approach to semiconductor production technology is facilitated.

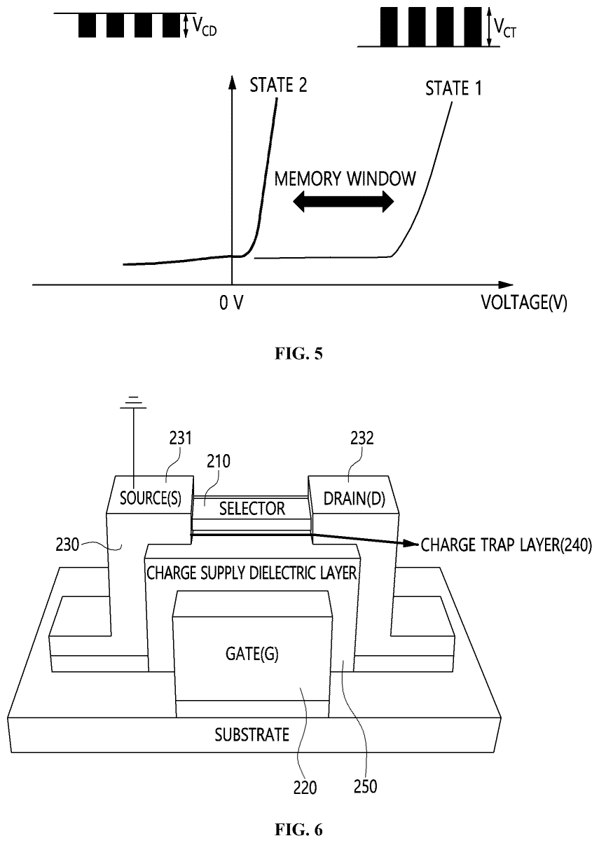

FIG. 6 is a perspective view of a charge trap-controlled selector-memory device having a three-terminal structure according to a further embodiment.

Referring to FIG. 6, the charge trap-controlled selector-memory device having a three-terminal structure according to the further embodiment may include a gate electrode 220, a gate dielectric layer 250 formed to contact one surface of the gate electrode 220, a charge trap layer 240 formed on the top of the gate dielectric layer 250 to trap electrons or holes, a selector 210 formed on the top of the charge trap layer 240, a drain electrode 232 connected to one side of the selector 210 on the top of the gate dielectric layer 250, and a source electrode 231 connected to the other side of the selector 210 on the top of the gate dielectric layer 250.

Although a bottom gate structure is illustratively shown in FIG. 6, this is only an example, and the present disclosure is not limited thereto. That is, the charge trap-controlled selector-memory device having a three-terminal structure according to the embodiment may also be implemented in the form of a top-gate structure.

Meanwhile, the gate dielectric layer 250 illustrated in FIG. 6, may be a normal dielectric layer or a charge supply dielectric layer such as that illustrated in FIG. 4.

Also, the charge trap layer 240 may have a small thickness of 0.5 to 10 nm, as illustrated in FIG. 4.

Further, the selector 210 may have a thickness of 5 to 50 nm.

Furthermore, the drain electrode 232 or the source electrode 231 may be manufactured using a semiconductor pattern formation technology.

In the charge trap-controlled selector-memory device having a three-terminal structure according to the further embodiment, the charge trap layer 240 traps electrons or holes supplied from the selector 210 or the charge supply dielectric layer 250 as a voltage pulse or a DC voltage is applied to the gate electrode 220. By means of this structure, the threshold voltage of the selector 210 may be modulated.

That is, the electrons or holes supplied from the selector 210 or the charge supply dielectric layer 250 may be trapped in the charge trap layer 240 or detrapped from the charge trap layer 240 by applying the voltage pulse to the gate electrode 220. Through this structure, the threshold voltage of a two-terminal selector device, in which a drain current sharply increases according to a drain voltage, changes, thus indicating a memory function.

When a positive voltage pulse or a negative voltage pulse is applied to the gate electrode 220, the threshold voltage of the selector in a drain voltage-drain current curve changes due to the electrons or holes trapped in the charge trap layer 240.

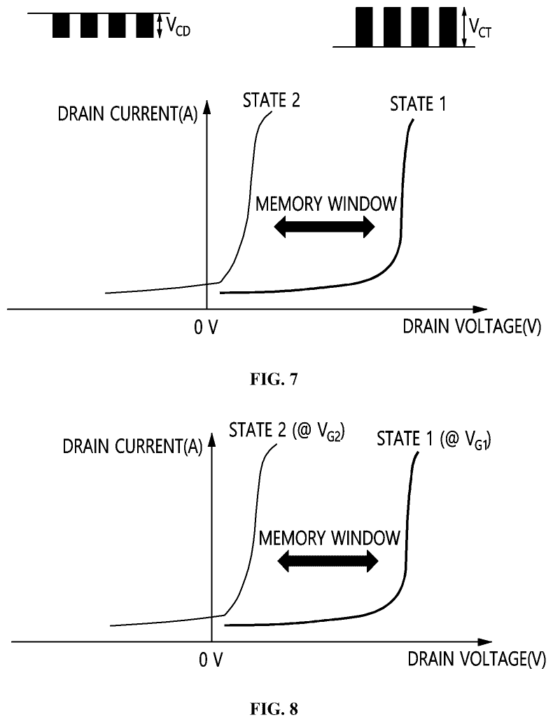

FIG. 7 is a diagram illustrating an example of memory modulation characteristics using a gate pulse of a three-terminal transistor device in a charge trap-controlled selector-memory device having a three-terminal structure according to a further embodiment, and FIG. 8 is a diagram illustrating an example of memory modulation characteristics using a read voltage of a three-terminal transistor device in the charge trap-controlled selector-memory device having a three-terminal structure according to the further embodiment.

Referring to FIG. 7, changes in a drain voltage and a drain current indicating the memory characteristics of a three-terminal device using a gate pulse are depicted, and the function of the selector memory may be indicated by controlling different threshold voltages corresponding to state 1 and state 2.

Further, an additional method that is capable of modulating the threshold voltage of the selector may be implemented as a scheme for modulating the threshold voltage while changing a DC voltage in the state in which a DC voltage is applied without applying a pulse to the gate electrode. The applied voltage is defined as a read voltage V_{read} for convenience of description.

When the values of V_{read} are V_{G1} and V_{G2}, respectively, electrons or holes are occasionally trapped in or detrapped from the charge trap layer under respective gate voltages, whereby the threshold voltage may be controlled.

Referring to FIG. 8, a relationship between a drain voltage and a drain current in memory modulation characteristics indicating that the threshold voltage is modulated by controlling the value of V_{read} is illustrated.

This case is advantageous in that the threshold voltage can be controlled by simply setting only the DC value of a gate voltage without separately applying a voltage pulse to the gate electrode.

Meanwhile, as semiconductor devices become more highly integrated, transistors having a three-dimensional (3D) structure are developed.

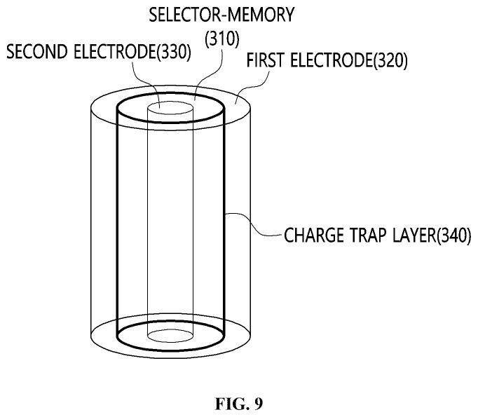

FIG. 9 is a sectional perspective view of a cylindrical charge trap-controlled selector-memory device having a two-terminal structure according to a further embodiment.

Referring to FIG. 9, the charge trap-controlled selector-memory device according to the further embodiment may include cylindrical selector memory 310, a cylindrical first electrode 320 which accommodates the selector memory 310 therein and to which a voltage is applied, a cylindrical second electrode 330 which is inserted into the selector memory 310 and is grounded, and an ultra-thin film charge trap layer 340 which is inserted into an interface between the selector memory 310 and the first electrode 320 or the second electrode 330 to trap electrons or holes as a voltage is applied to the first electrode 320.

Here, the selector memory 310 may be formed of a chalcogenide-based compound, and may contain at least one of binary or ternary materials or a combination thereof.

Here, the charge trap-controlled selector-memory device may further include a charge supply layer (not illustrated) which is stacked between the charge trap layer 340 and the second electrode 330 or the first electrode 320 to supply electrons or holes.

This is only an embodiment, and even a three-terminal structure may also be manufactured in a 3D structure in a similar manner, and the present disclosure includes such a selector-memory device structure having a 3D structure.

As described above, according to described embodiments, the charge trap-controlled selector-memory device has been presented based on the structures and materials of the two-terminal and three-terminal devices.

The described embodiments operate based on charge trapping and have high operational stability and durability, high operating speed, and CMOS compatibility, and thus satisfying the key requirements to be provided as next-generation memory.

The memory device may be directly utilized as a Selector Only Memory (SOM) device, fine semiconductor manufacturing processes such as Atomic Layer Deposition (ALD) may be mainly applied, and memory having a three-dimensional (3D) structure may also be manufactured. Therefore, even in the case where a line width is reduced in the future, the memory device may be utilized, and may be applied as a next-generation memory device.

In addition, it is expected to have a low barrier to mass production due to high compatibility with existing semiconductor processes, scalability to large-area manufacturing, and high durability of materials.

When such a memory device can be implemented, there are many advantages compared to existing High Bandwidth Memory (HBM) technologies in terms of delay times (latency) between computational units and memory of current artificial intelligence semiconductor, as well as processing of large volumes of data. Furthermore, integration with computing devices in the future may be facilitated, and thus it is expected to remarkably reduce power consumption.

According to the embodiments, there can be proposed a selector-memory device that meets a recent increase in a demand for an artificial intelligence semiconductor and that is capable of replacing conventional Dynamic Random Access Memory (DRAM) as next-generation low-power and high-speed memory, which conforms to such a demand increase.

According to the embodiments, there can be proposed a device that can perform two functions of a selector and memory using binary or, at most, ternary compound materials while operating as a clearer conduction mechanism.

Although the embodiment of the present disclosure has been disclosed, those skilled in the art will appreciate that the present disclosure can be implemented as other concrete forms, without departing from the scope and spirit of the disclosure as disclosed in the accompanying claims. Therefore, it should be understood that the exemplary embodiment is only for illustrative purpose and do not limit the scope of the present disclosure.

What is claimed is:

1. A charge trap-controlled selector-memory device, comprising:
a selector memory;
an upper electrode stacked on a top of the selector memory and configured such that a voltage is applied to the upper electrode;
a lower electrode stacked on a bottom of the selector memory and grounded; and
an ultra-thin film charge trap layer stacked on an interface between the selector memory and the upper electrode or the lower electrode, and configured to trap electrons or holes as the voltage is applied to the upper electrode.

2. The charge trap-controlled selector-memory device of claim 1, wherein:
the selector memory is formed of a chalcogenide-based compound, and includes at least one of binary or ternary materials, or a combination thereof, and
the selector memory is made of a material including SiTe, SiSeTe, ZnTe, and ZnSeTe.

3. The charge trap-controlled selector-memory device of claim 1, wherein the selector memory is manufactured to be deposited on the lower electrode using a semiconductor vacuum technique including Atomic Layer Deposition (ALD), sputter deposition, or chemical vapor deposition.

4. The charge trap-controlled selector-memory device of claim 1, wherein the selector memory has a thickness of 5 nm to 200 nm.

5. The charge trap-controlled selector-memory device of claim 1, wherein the ultra-thin film charge trap layer has a thickness of 0.5 nm to 10 nm.

6. The charge trap-controlled selector-memory device of claim 1, wherein the ultra-thin film charge trap layer is formed of one of an oxide and a sulfide.

7. The charge trap-controlled selector-memory device of claim 1, further comprising:
a charge supply layer stacked between the ultra-thin film charge trap layer and the lower electrode or the upper electrode to supply electrons or holes.

8. The charge trap-controlled selector-memory device of claim 1, wherein the charge supply layer is formed of one of an oxide and a sulfide.

9. The charge trap-controlled selector-memory device of claim 1, wherein the charge supply layer has a thickness of 5 nm to 50 nm.

10. A charge trap-controlled selector-memory device, comprising:
a gate electrode;
a gate dielectric layer formed to contact a first side surface of the gate electrode;
a charge trap layer formed on a top of the gate dielectric layer to trap electrons or holes;
a selector formed on a top of the charge trap layer;
a drain electrode connected to a first side of the selector on the top of the gate dielectric layer; and
a source electrode connected to a second side of the selector on the top of the gate dielectric layer.

11. The charge trap-controlled selector-memory device of claim 10, wherein the gate dielectric layer is a normal dielectric layer or a charge supply dielectric layer.

12. The charge trap-controlled selector-memory device of claim 10, wherein the selector has a thickness of 5 nm to 50 nm.

13. The charge trap-controlled selector-memory device of claim 11, wherein:
the charge trap layer traps electrons or holes supplied from the selector or a charge supply dielectric layer as a voltage pulse or a DC voltage is applied to the gate electrode, and
a threshold voltage of the selector is modulated.

14. A charge trap-controlled selector-memory device, comprising:
a cylindrical first electrode configured such that a voltage is applied thereto;
a cylindrical selector memory inserted into the first electrode;
a cylindrical second electrode inserted into the selector memory and grounded; and
an ultra-thin film charge trap layer inserted into an interface between the selector memory and the second electrode or the first electrode, and configured to trap electrons or holes as a voltage is applied to the first electrode.

15. The charge trap-controlled selector-memory device of claim 14, wherein the selector memory is formed of a chalcogenide-based compound, and includes at least one of binary or ternary materials, or a combination thereof.

16. The charge trap-controlled selector-memory device of claim 14, further comprising:
a charge supply layer stacked between the charge trap layer and the second electrode or the first electrode to supply electrons or holes.
